(19) United States
(12) Patent Application Publication
(10) Pub. No.: US 2014/0022208 A1
(43) Pub. Date: Jan. 23, 2014

(54) COLOR FILTER SUBSTRATE AND TOUCH DISPLAY PANEL USING SAME

(71) Applicant: TIANJIN FUNAYUANCHUANG TECHNOLOGY CO.,LTD., Tianjin (CN)

(72) Inventor: HO-CHIEN WU, New Taipei (TW)

(73) Assignee: TIANJIN FUNAYUANCHUANG TECHNOLOGY CO.,LTD., Tianjin (CN)

(21) Appl. No.: 13/948,225

(22) Filed: Jul. 23, 2013

(30) Foreign Application Priority Data
Jul. 23, 2012 (CN) 2012102551029

(51) Int. Cl. H03K 17/96; G06F 3/044

(52) U.S. Cl. CPC H03K 17/9622; G06F 3/044
USPC 345/174; 200/600

(57) ABSTRACT

An exemplary color filter substrate for a touch display panel includes a base and a capacitive touch sensitive structure located a first side of the base. The capacitive touch sensitive structure includes a first conductive layer, a second conductive layer, and a polarizer located between the first conductive layer and the second conductive layer.

### CROSS-REFERENCE TO RELATED APPLICATIONS

This application claims all benefits accruing under 35 U.S.C. §119 from China Patent Application No. 201210255102.9, filed on Jul. 23, 2012 in the China Intellectual Property Office, the content of which is hereby incorporated by reference. This application is related to commonly-assigned applications entitled, “POLARIZER”, U.S. application Ser. No. 13/730,711, filed Dec. 28, 2012; “POLARIZER”, U.S. application Ser. No. 13/730,884, filed Dec. 29, 2012, “LIQUID CRYSTAL DISPLAY MODULE”, U.S. application Ser. No. 13/837,266, filed Mar. 15, 2013, and “LIQUID CRYSTAL DISPLAY MODULE”, U.S. application Ser. No. 13/837, 359 filed Mar. 15, 2013; “LIQUID CRYSTAL DISPLAY MODULE”, U.S. application Ser. No. 13/869,958, filed Apr. 25, 2013, and “LIQUID CRYSTAL DISPLAY MODULE”, U.S. application Ser. No. 13/869, 959 filed Apr. 25, 2013; “METHOD FOR MAKING LIQUID CRYSTAL DISPLAY MODULE”, U.S. application Ser. No. 13/869,961, filed Apr. 25, 2013; “METHOD FOR MAKING LIQUID CRYSTAL DISPLAY MODULE”, U.S. application Ser. No. 13/869,964, filed Apr. 25, 2013, and “COLOR FILTER SUBSTRATE, TOUCH DISPLAY PANEL AND TOUCH DISPLAY DEVICE” filed ______ (Atty. Docket No. US46696).

### BACKGROUND

1. Technical Field

The present disclosure relates to a color filter substrate, a touch display panel using the same.

2. Description of Related Art

Touch display panels usually have a color filter substrate and a touch screen attached to the color filter substrate via optical clear adhesive. However, because of the optical clear adhesive, thickness of the touch display panels is hard to reduce. Thus, the touch display panels may be not meet requirements of users.

What is needed is to provide a means that can overcome the above-described limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is a cross-sectional view of a touch display panel according to a first embodiment of the present disclosure, the touch display panel including a first conductive layer, a second conductive layer, and a polarizer.

FIG. 2 is a plane view of the first conductive layer of the touch display panel of FIG. 1.

FIG. 3 is a plane view of the second conductive layer of the touch display panel of FIG. 1.

FIG. 4 is a schematic view of a carbon nanotube film of the second conductive layer of FIG. 3.

FIG. 5 is a cross-sectional view of the polarizer of the touch display panel of FIG. 1.

FIG. 6 is a plane view of a capacitive touch sensitive structure of the touch display panel of FIG. 1.

FIG. 7 is a plane view of a first conductive layer of a touch display panel according to a second embodiment of the present disclosure.

FIG. 8 is a plane view of a first conductive layer of a touch display panel according to a third embodiment of the present disclosure.

FIG. 9 is a plane view of a first conductive layer of a touch display panel according to a fourth embodiment of the present disclosure.

FIG. 10 is a plane view of a first conductive layer of a touch display panel according to a fifth embodiment of the present disclosure.

FIG. 11 is a schematic view of a carbon nanotube film of the first conductive layer of FIG. 10.

FIG. 12 is a cross-sectional view of a touch display panel according to a sixth embodiment of the present disclosure.

FIG. 13 is a cross-sectional view of a touch display panel according to a seventh embodiment of the present disclosure.

FIG. 14 is a plane view of a capacitive touch sensitive structure of the touch display panel of FIG. 3.

### DETAILED DESCRIPTION

Reference will now be made to the drawings to describe various embodiments in detail.

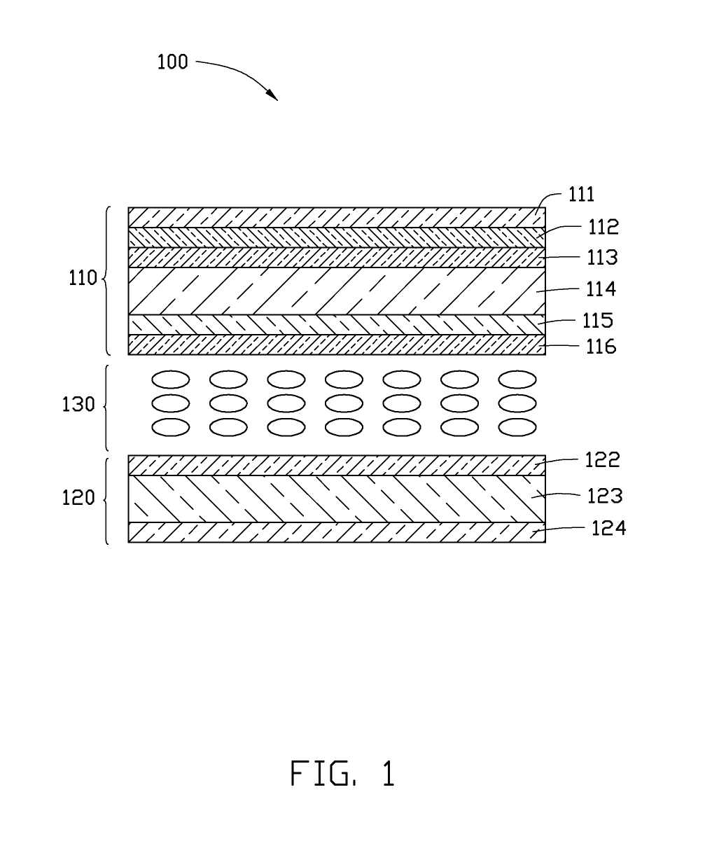

Referring to FIG. 1, a touch display panel 100 according to an embodiment of the present disclosure includes a first substrate 110, a second substrate 120 facing the first substrate 110, and a liquid crystal layer 130 sandwiched between the first substrate 110 and the second substrate 120. The first substrate 110 can be a color filter substrate and includes a first conductive layer 111, an upper polarizer 112, a second conductive layer 113, a first base 114, a color filter layer 115, and a common electrode layer 116. The second substrate 120 includes a driving layer 122, a second base 123, and a lower polarizer 124.

The first base 114 can be a glass substrate. A side of the first base 114 away from the liquid crystal layer 130 is defined as a first side of the first base 114, and a side of the first base 114 adjacent to the liquid crystal layer 130 is defined as a second side of the first base 114. The upper polarizer 112, the first conductive layer 111, and the second conductive layer 113 are located on the first side of the first base 114. In the embodiment, the second conductive layer 113 is located on a surface of the first side of the first base 114, the upper polarizer 112 is located on a surface of the second conductive layer 113 away from the first base 114, and the first conductive layer 111 is located on a surface of the upper polarizer 112 away from the second conductive layer 113. The color filter layer 115 is located on a surface of the second side of the first base 114, and the common electrode layer 116 is located on a surface of the color filter layer 115 away from the first base 114.

The second base 123 can be a glass substrate. The driving layer 122 can be a thin film transistor driving layer and is configured to cooperate with the common electrode layer 116 to drive the liquid crystal layer 130. The driving layer 122 is located at a side of the second base 123 adjacent to the liquid crystal layer 130, and the lower polarizer 124 is attached to a surface of the second base 123 away from the liquid crystal layer 130. The driving layer 122 may include a plurality of gate lines, a plurality of data lines, and a plurality of pixel regions defined by the gate line and data lines crossing the gate lines. Each pixel region can include a thin film transistor and a pixel electrode electrically coupled to the thin film transistor.

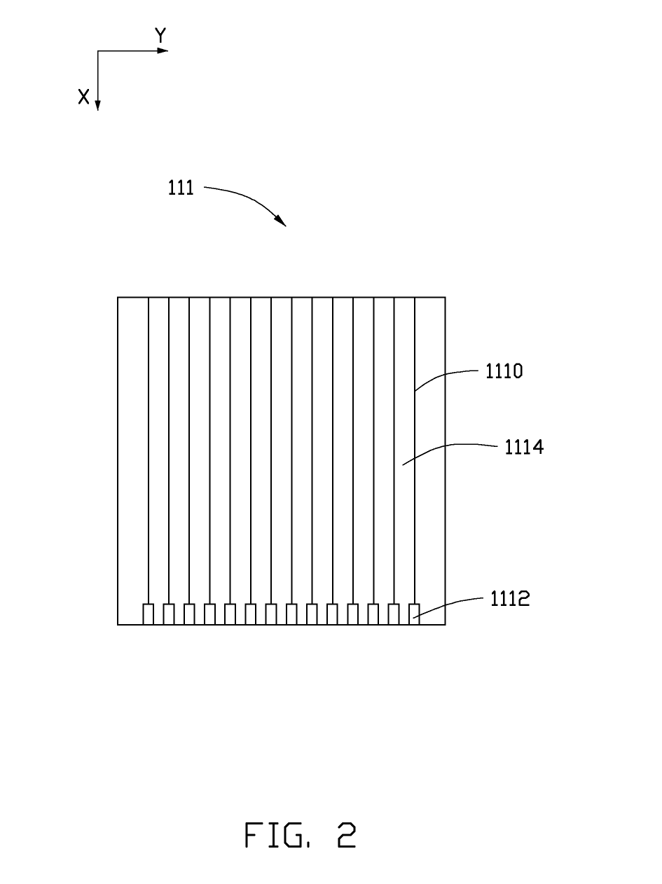

Referring to FIG. 2, the first conductive layer 111 is a transparent conductive layer, and the first conductive layer 111 includes a plurality of sensitive lines 1110 each extending along a first direction X and a plurality of first electrodes 1112 corresponding to the plurality of sensitive lines 1110. The plurality of first electrodes 1112 are arranged at a side of the first conductive layer 111, and each first electrode 1112 is electrically connected to a corresponding one sensitive line 110. In the embodiment, the sensitive line 1110 is stripe shaped, and an opening 1114 is defined to be located between the two adjacent sensitive lines 1110. The opening 114 extends along the first direction X and has a stripe shape. Moreover, the first conductive layer 111 includes material selected from the group consisting of indium tin oxide and indium zinc oxide. The first electrodes 1112 can be made of silver, and the first electrodes 1112 are configured to electrically connect to an external touch sensitive circuit.

The first conductive layer 111 is a topmost layer of the touch display panel 100 and configured to face users. In the embodiment, the first conductive layer 111 also serves as a shielding layer of the touch display panel 100 to reduce electromagnetic radiation of the touch display panel 100. In detail, a width of the opening 1114 can be less than a width of most electromagnetic wave.

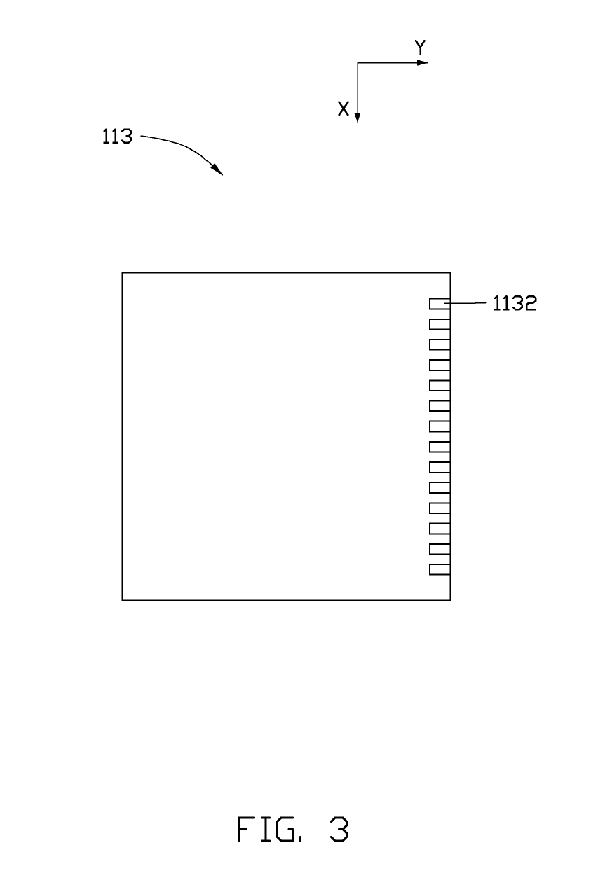

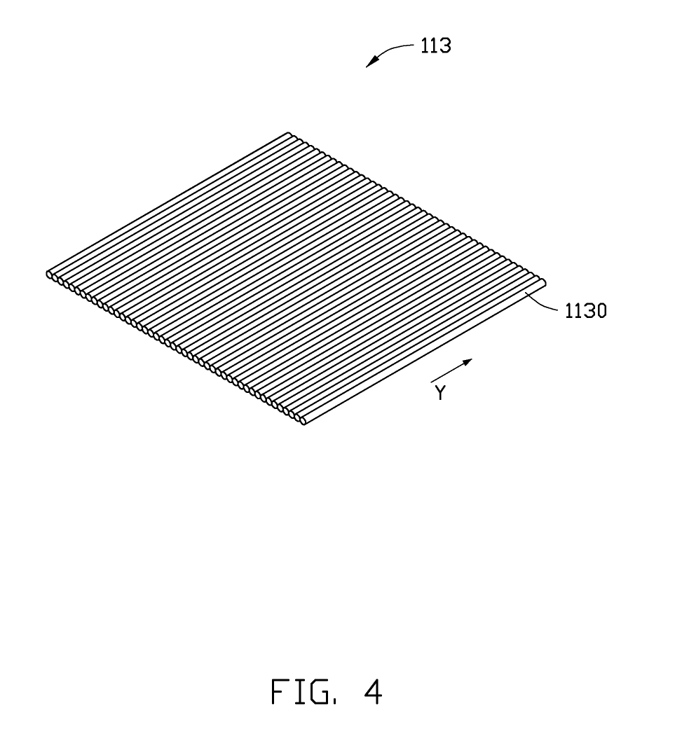

Referring to FIG. 3, the second conductive layer 113 is a continuous conductive layer. The second conductive layer 113 exhibits electrical anisotropy and has the lowest resistivity along a second direction Y perpendicular to the first direction X. That is, a resistivity of the second conductive layer 113 along the second direction Y is greater than a resistivity of the second conductive layer 113 along any other directions. In the embodiment, the second conductive layer 113 is a carbon nanotube (CNT) film. Referring to FIG. 4, the carbon nanotube (CNT) film includes a plurality of orderly arranged carbon nanotubes 1130 where each carbon nanotube 1130 extends along the second direction Y. Each carbon nanotube 1130 is attached to the adjacent carbon nanotube 1130 by van der Waals forces. The second conductive layer 113 may further includes a plurality of second electrodes 1132. The plurality of second electrodes 1132 is positioned on the CNT film and electrically connected to the CNT film. The second electrodes 1132 can be made of silver, and the second electrodes 1132 are configured to electrically connect to an external touch driving circuit.

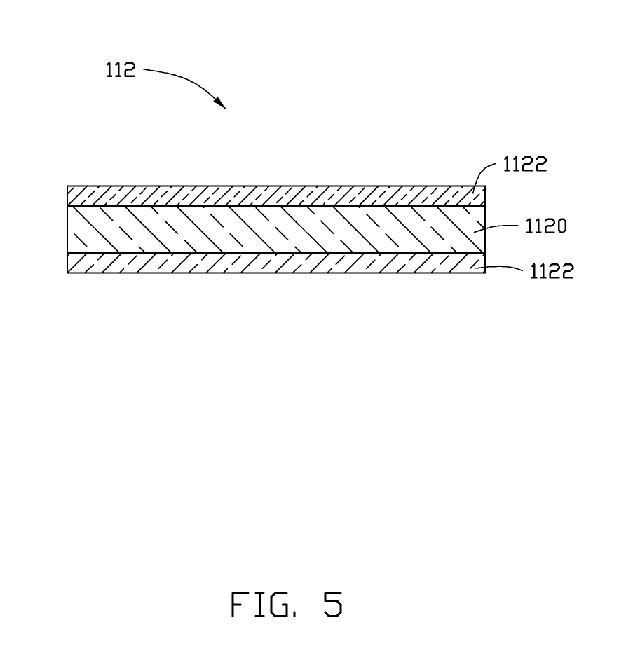

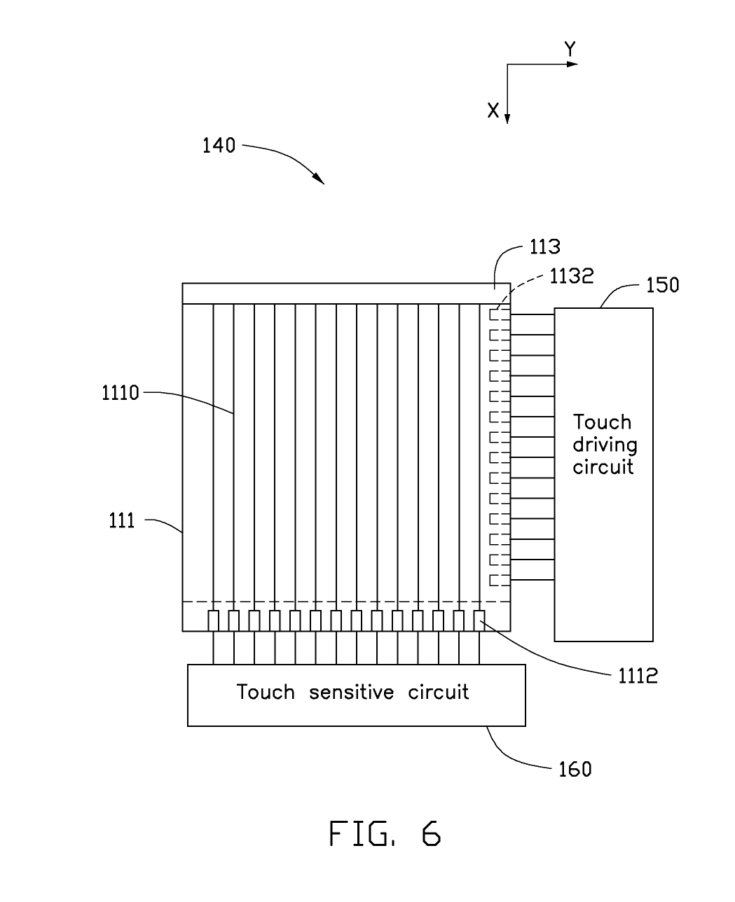

Referring to FIG. 5, the upper polarizer 112 is an insulation layer and includes two protection layers 1122 and a polarizing layer 1120 sandwiched between the two protection layers 1122. In the embodiment, the upper polarizer 112 is located between the first conductive layer 111 and the second conductive layer 113 to insulate the first conductive layer 111 and the second conductive layer 113, such that the first conductive layer 111, the second conductive layer 113, and the upper polarizer 112 sandwiched therebetween define a capacitive touch sensitive structure 140 as shown in FIG. 6. In a manufacturing process of the touch display panel 100, the first conductive layer 111 and the second conductive layer 113 can be adhere to two opposite surfaces of the upper polarizer 112, then the first conductive layer 111, the second conductive layer 113, and the upper polarizer 112 as one body are attached to a surface of the first base 114 away from the liquid crystal layer 130.

Referring to FIG. 6, in the capacitive touch sensitive structure 140, the plurality of sensitive lines 1110 and the second conductive layer 113 define a plurality of touch capacitors. When the touch display panel 100 is in operation, a touch driving circuit 150 provides a plurality of touch scanning signals to the second conductive layer 113 via the plurality of second electrodes 1132, and a touch sensitive circuit 160 detect voltage change of the first electrodes 1112 to obtain positions of touch operation applied to the touch display panel 100.

In an alternative embodiment, the touch driving circuit 150 and the touch sensitive circuit 160 can switch positions, that is, when the touch display panel 100 is in operation, the touch driving circuit 150 provides a plurality of touch scanning signals to the first conductive layer 111 via the plurality of first electrodes 1112, and a touch sensitive circuit 160 detects voltage change of the second electrodes 1132 to obtain positions of touch operation applied to the touch display panel 100.

In summary, the touch display panel 100 has the capacitive touch sensitive structure directly formed on the first substrate 110, the upper polarizer 112 can serve as a base and a dielectric layer of the capacitive touch sensitive structure 140, such that the touch display panel 100 can reduce a thickness of an external base and/or a dielectric layer of a touch panel comparing to the existing touch display panel. Furthermore, the first conductive layer 111 also serves as the shielding layer of the touch display panel 100, such that the touch display panel 100 can further reduce a thickness of an external shielding layer.

In addition, the first conductive layer 111 is provided a direct current voltage by the touch sensitive circuit 160, and the width of the opening 1114 of the first conductive layer 111 is less than a width of most electromagnetic waves, these also cause the electromagnetic radiation of the touch display panel 100 provided to the users can be further reduced.

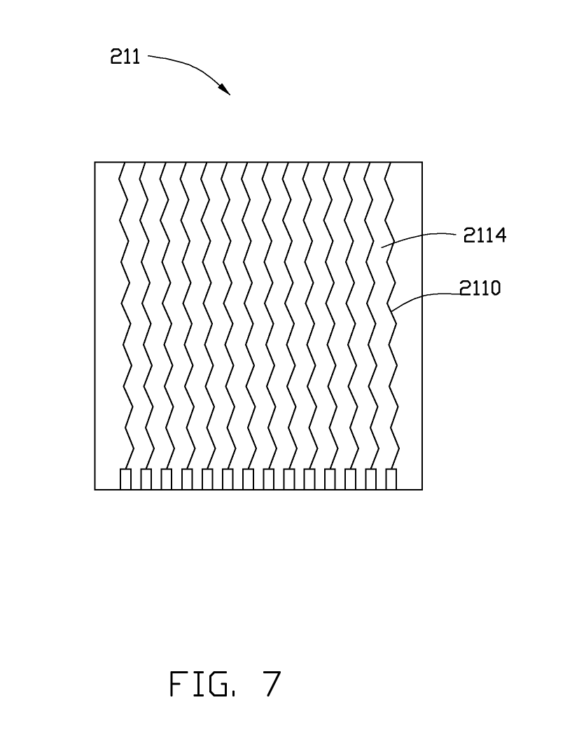

Referring to FIG. 7, a first conductive layer 211 of a touch display panel according to a second embodiment is shown. The first conductive layer 211 differs from the first conductive layer 111 in that each sensitive line 2110 and each opening 2114 are arranged in a sawtooth manner. Because of the sawtooth opening 2114, the electromagnetic radiation of the touch display panel of the second embodiment may be further reduced.

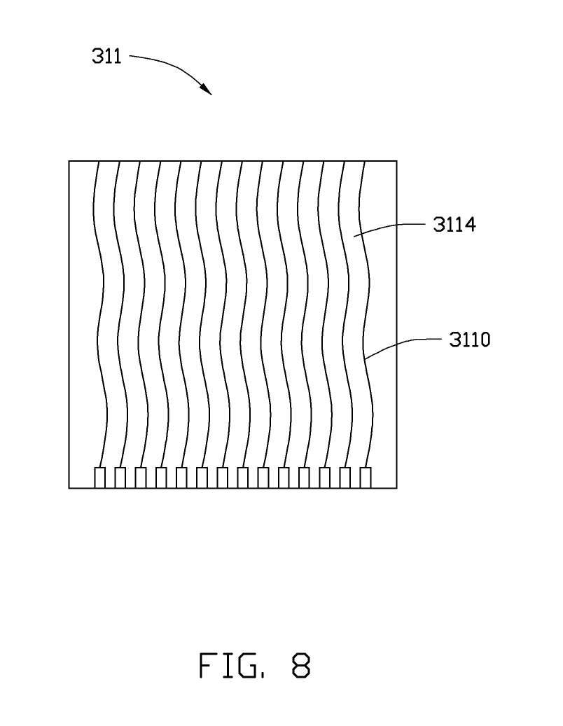

Referring to FIG. 8, a first conductive layer 311 of a touch display panel 200 according to a third embodiment is shown is shown. The first conductive layer 311 differs from the first conductive layer 111 in that each sensitive line 3110 and each opening 3114 are wave-shaped. Because of the wave-shaped opening 3114, the electromagnetic radiation of the touch display panel of the second embodiment is also further reduced.

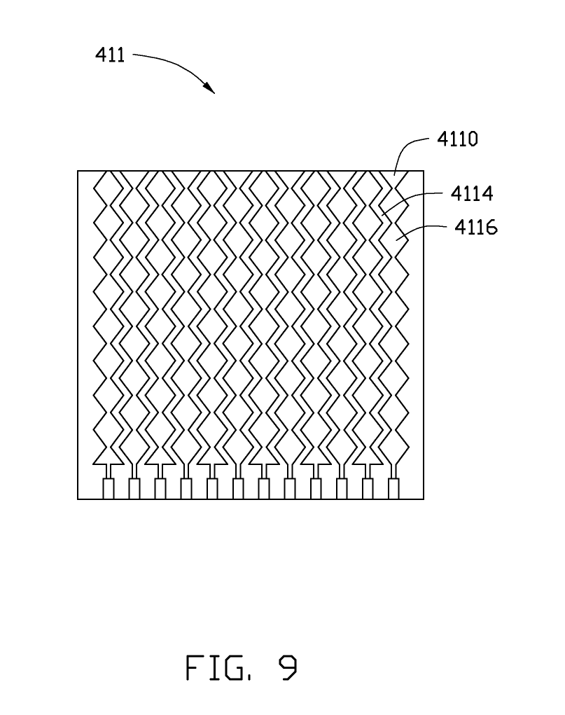

Referring to FIG. 9, a first conductive layer 411 of a touch display panel 200 according to a fourth embodiment is shown. The first conductive layer 411 differs from the first conductive layer 211 in that each sensitive line 4110 comprises a plurality of diamond shaped portions 4116 connected to each other, the diamond shaped portions 4116 of one sensitive line 4110 of the two adjacent sensitive lines 4110 are alternately arranged with the diamond shaped portions 4116 of the other sensitive line 4110 of the two adjacent sensitive lines 4110, and the two adjacent sensitive lines 4110 define a sawtooth shaped opening 4114.

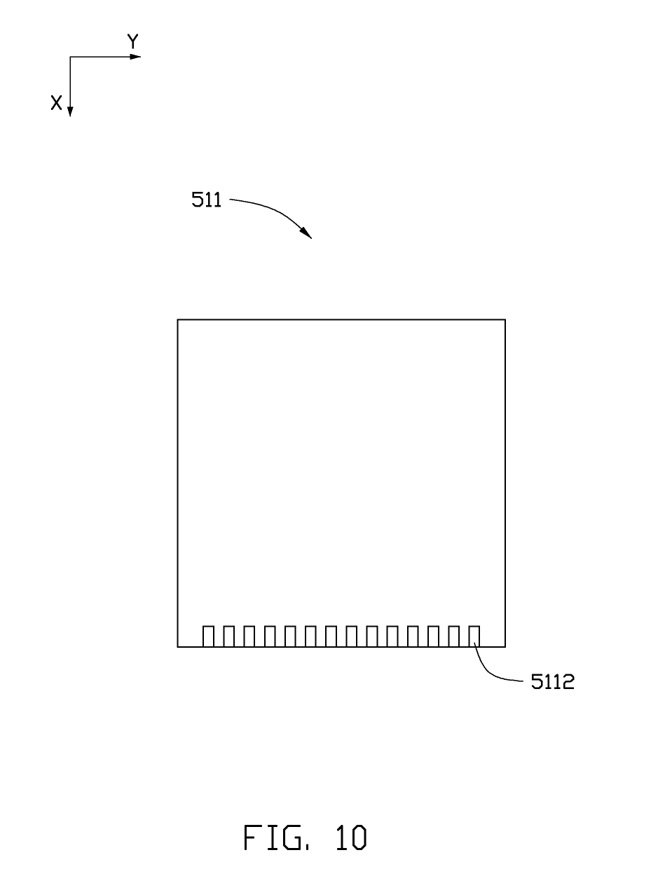

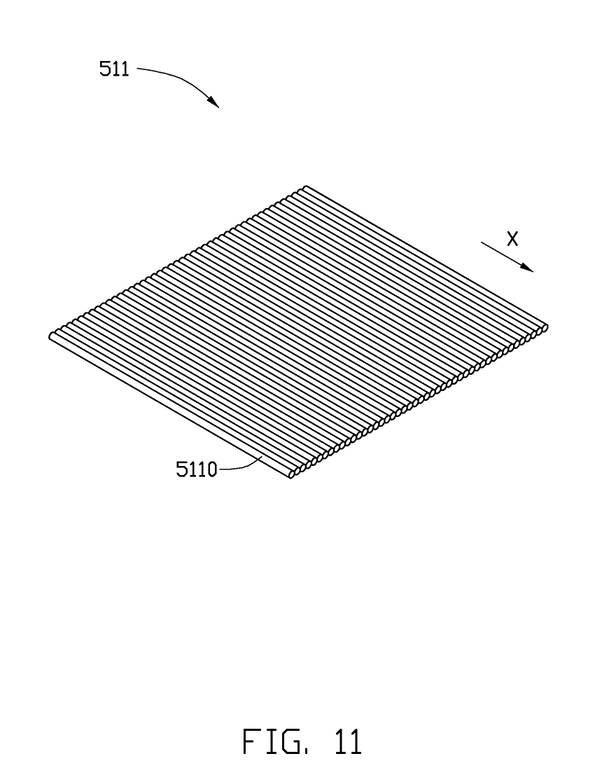

Referring to FIG. 10, a first conductive layer 511 of a touch display panel 200 according to a fifth embodiment is shown. The first conductive layer 511 differs from the first conductive layer 111 in that the first conductive layer 511 is a continuous conductive layer. In detail, the first conductive layer 511 exhibits electric anisotropy and has the lowest resistivity along the first direction X. In the embodiment, the first conductive layer 51 is a carbon nanotube (CNT) film. Referring to FIG. 11, the carbon nanotube (CNT) film includes a plurality of orderly arranged carbon nanotubes 5110 wherein each carbon nanotube 1130 extends along the second direction Y. Each carbon nanotube 5110 is attached to the adjacent carbon nanotube 5110 by van der Waals forces. The first conductive layer 51 may further includes a plurality of first electrodes 5112. The plurality of first electrodes 5112 are positioned on the CNT film and electrically connected to the CNT film. The first electrodes 5112 can be made of silver, and the first electrodes 5112 are configured to electrically connect an external touch sensitive circuit. In the fifth embodiment, because the first conductive layer 511 which is also served as the shielding layer is a continuous conductive layer, that causing more electromagnetic radiation of the touch display panel of the second embodiment is reduced.

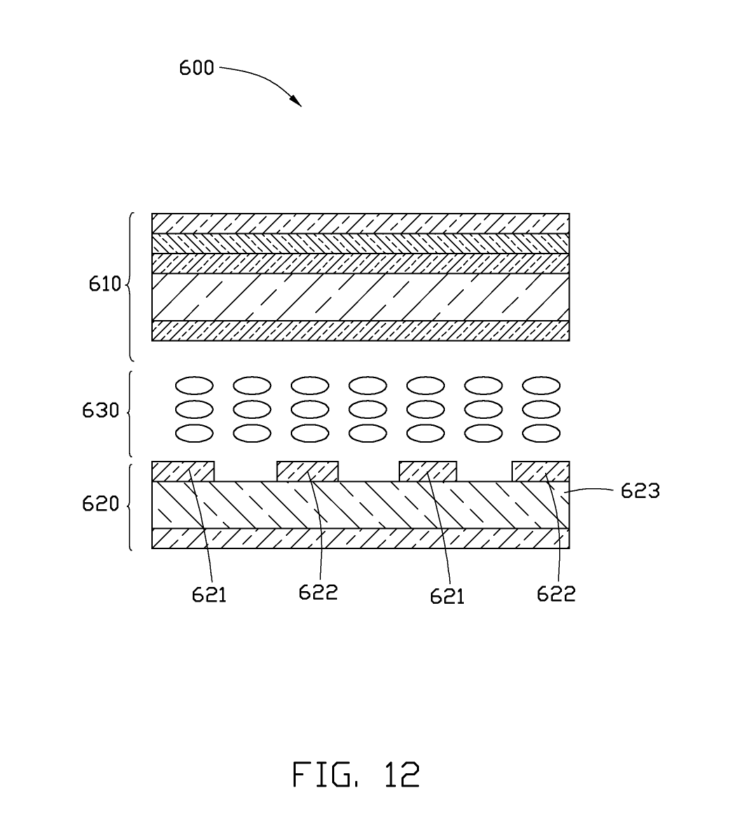

Referring to FIG. 12, a touch display panel 600 according to a sixth embodiment differs from the touch display panel 100 in that the touch display panel 600 is an in-plane switch (IPS) mode touch display panel. A first substrate 610 may not have a common electrode layer, but a second substrate 620 includes a plurality of common electrodes 621 and a plurality of pixel electrodes 622. The plurality of common electrodes 621 and the plurality of pixel electrodes 622 are located at a surface of a second base 623 adjacent to a liquid crystal layer 630, and the plurality of common electrodes 621 and the plurality of pixel electrodes 622 are alternatively arranged one by one. The common electrodes 621 cooperate with the pixel electrodes 622 to drive the liquid crystal layer 130 to rotate in a horizontal plane.

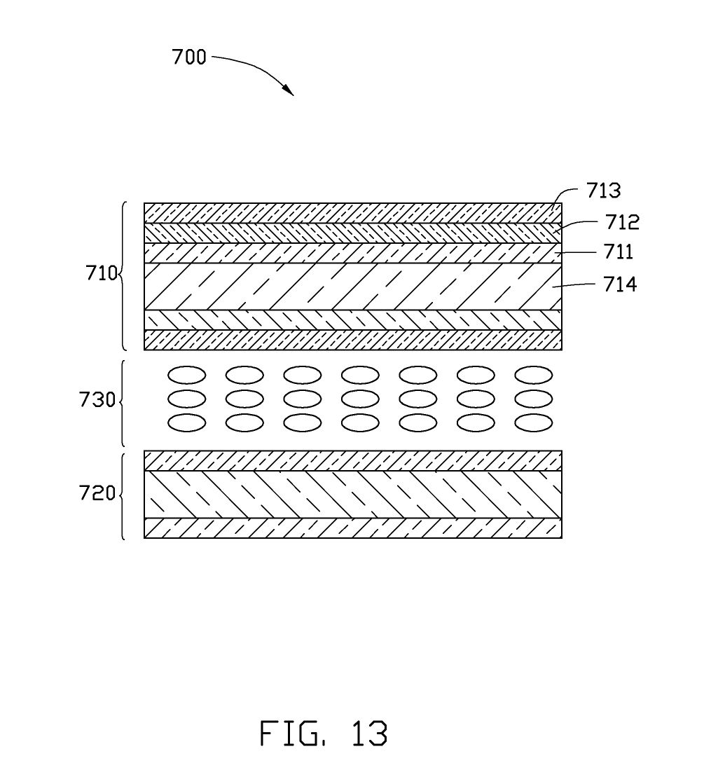

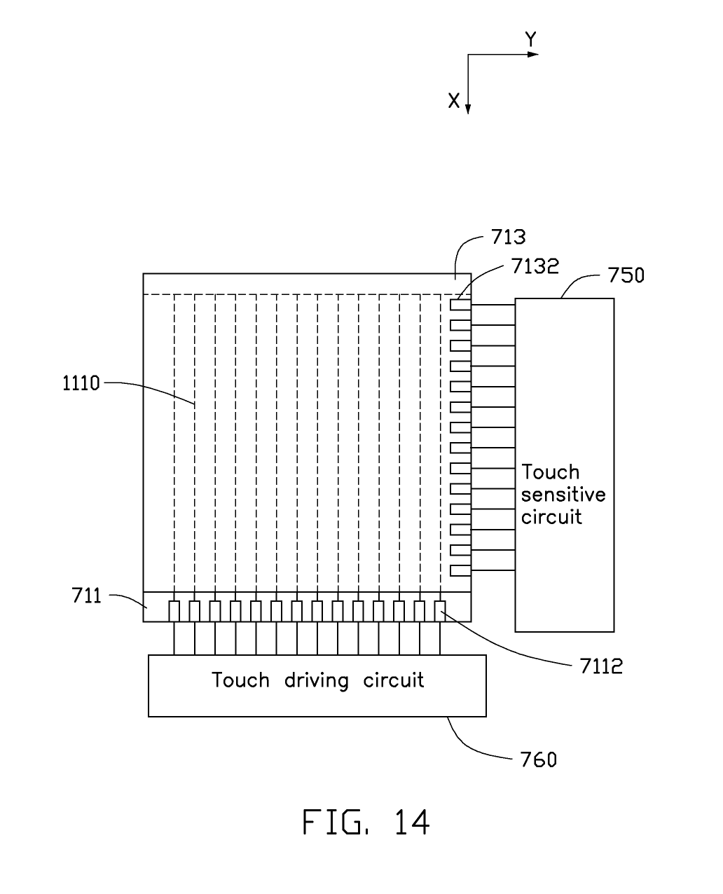

Referring to FIG. 13 and FIG. 14, a touch display panel 700 according to a seventh embodiment is shown. The touch display panel 700 differs from the touch display panel 100 in that a first conductive layer 711 and a second conductive layer 713 have switched positions. In detail, the first conductive layer 711 is located between a first base 714 and an upper polarizer 712, and the first conductive layer 711 is electrically connected to a touch driving circuit 750 via the first electrodes 7112 to receive touch scanning signals. The second conductive layer 713 is located on a side of the upper polarizer 712 away from the first conductive layer 711, and the second conductive layer 713 is electrically connected to a touch sensitive circuit 760 via the second electrodes 7132 to receive touch sensitive signals. The touch sensitive circuit 760 detects detect voltage change of the second electrodes 7132 to obtain positions of touch operation applied to the touch display panel 700.

In a manufacturing process of the touch display panel 700, the first conductive layer 711 can be directly formed on the first base 714, and the second conductive layer 713 can be attached to the upper polarizer 712, then the second conductive layer 713, and the upper polarizer 712 as one body are attached to the first conductive layer 711. It can be seen that, the manufacturing process of the touch display panel 700 may be simple than that of the touch display panel 100.

It is to be understood that even though numerous characteristics and advantages of the present embodiments have been set forth in the foregoing description, together with details of the structures and functions of the embodiments, the disclosure is illustrative only; and that changes may be made in detail, especially in matters of shape, size, and arrangement of parts, within the principles of the embodiments, to the full extent indicated by the broad general meaning of the terms in which the appended claims are expressed.

1. A color filter substrate for a touch display panel, comprising:
a base; and
a capacitive touch sensitive structure located a first side of the base, the capacitive touch sensitive structure comprising a first conductive layer, a second conductive layer, and a polarizer located between the first conductive layer and the second conductive layer.

2. The color filter substrate of claim 1, wherein the first conductive layer serves as a shielding layer of the touch display panel.

3. The color filter substrate of claim 2, wherein the second conductive layer is located between the polarizer and the base, and the shielding layer is located on a side of the polarizer away from the substrate.

4. The color filter substrate of claim 3, wherein the first conductive layer comprises a carbon nanotube (CNT) film comprising a plurality of carbon nanotubes orderly arranged along a first direction.

5. The color filter substrate of claim 3, wherein the first conductive layer comprises a plurality of sensitive lines each extending along a first direction, and the first conductive layer comprises material selected from the group consisting of indium tin oxide and indium zinc oxide.

6. The color filter substrate of claim 5, wherein two adjacent sensitive lines of the plurality of sensitive lines define an opening located between the two adjacent sensitive lines, and the opening is wave-shaped or sawtooth shaped.

7. The color filter substrate of claim 6, wherein each sensitive line is wave-shaped or sawtooth shaped, and the plurality of sensitive lines are parallel to each other.

8. The color filter substrate of claim 6, wherein each sensitive line comprises a plurality of diamond shaped portions connected to each other, the diamond shaped portions of one sensitive line of the two adjacent sensitive lines are alternately arranged with the diamond shaped portions of the other sensitive line of the two adjacent sensitive lines, and the two adjacent sensitive lines define a sawtooth shaped opening.

9. The color filter substrate of claim 5, wherein the second conductive layer comprises a carbon nanotube (CNT) film comprising a plurality of carbon nanotubes orderly arranged along a second direction.

10. The color filter substrate of claim 9, wherein the first direction is perpendicular to the second direction.

11. A touch display panel, comprising:
a first substrate comprising:
a base; and
a capacitive touch sensitive structure located a first side of the base, the capacitive touch sensitive structure comprising a first conductive layer, a second conductive layer, and a polarizer located between the first conductive layer and the second conductive layer.
a second substrate; and
a liquid crystal layer sandwiched between the first substrate and the second substrate.

12. The touch panel of claim 11, wherein the first conductive layer comprises a carbon nanotube (CNT) film comprising a plurality of carbon nanotubes orderly arranged along a first direction.

13. The touch panel of claim 12, wherein the first conductive layer comprises a plurality of sensitive lines each extending along a first direction, and the first conductive layer comprises material selected from the group consisting of indium tin oxide or indium zinc oxide.

14. The touch panel of claim 13, wherein two adjacent sensitive lines of the plurality of sensitive lines define an opening located between the two adjacent sensitive lines, and the opening is wave-shaped or sawtooth shaped.

15. The touch panel of claim 14, wherein two adjacent sensitive lines of the plurality of sensitive lines define an opening located between the two adjacent sensitive lines, and the opening is wave-shaped or sawtooth shaped.

16. The touch panel of claim 15, wherein each sensitive line comprises a plurality of diamond shaped portions connected to each other, the diamond shaped portions of one sensitive line of the two adjacent sensitive lines are alternately arranged with the diamond shaped portions of the other sensitive line of the two adjacent sensitive lines, and the two adjacent sensitive lines define a sawtooth shaped opening.

17. The touch panel of claim 12, wherein the second conductive layer comprises a carbon nanotube (CNT) film comprising a plurality of carbon nanotubes orderly arranged along a second direction.

18. The touch panel of claim 17, wherein the first direction is perpendicular to the second direction.

19. The touch panel of claim 17, further comprising a plurality of first electrode electrically connected to the first conductive layer and a plurality of second electrode electrically connected to the second conductive layer, wherein the second conductive layer are electrically couple to a touch scanning layer to receive touch scanning signals, and a touch sensitive circuit are electrically coupled to the first conductive layer to detect voltage change of the first electrode to obtain positions of touch operation applied to the capacitive touch sensitive structure.

20. A touch display panel, comprising:
a first substrate comprising:
a base; and
a capacitive touch sensitive structure located a first side of the base, the capacitive touch sensitive structure comprising a polarizer, a conductive layer located between the polarizer and the base, and a shielding layer located a side of the polarizer away from the base;
a second substrate; and
a liquid crystal layer sandwiched between the first substrate and the second substrate.
